(19) United States
(12) Patent Application Publication
(10) Pub. No.: US 2024/0284599 A1
(43) Pub. Date: Aug. 22, 2024

(54) Method for preparing novel material layer structure of circuit board and article thereof

(71) Applicant: LongKai LI, Chongqing (CN)

(72) Inventor: LongKai LI, Chongqing (CN)

(21) Appl. No.: 18/617,514

(22) Filed: Mar. 26, 2024

Related U.S. Application Data
(63) Continuation of application No. 17/753,107, filed on Feb. 18, 2022.

(51) Int. Cl. H05K 3/00; H05K 1/05

(52) U.S. Cl. CPC H05K 3/0011; H05K 1/056; H05K 2201/0112; H05K 2201/0129; H05K 2201/0141; H05K 2201/0145; H05K 2201/015; H05K 2201/0154; H05K 2203/1581

(57) ABSTRACT

The present invention discloses a method for preparing a novel material layer structure of a circuit board, comprising the steps of: (1) combining a film with a copper layer to form an FCCL single-sided board; (2) applying a semi-cured functional material layer on a back side of the film of the FCCL single-sided board, wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive to form a novel material layer structure for a circuit board. An article prepared by performing the above methods is also disclosed. The prepared novel material layer structure of the circuit board has high-frequency characteristics and/or copper ion migration resistance, and can be used as an integral structure. In the circuit board manufacturing process, it can be manufactured as the circuit board manufacturing material to be different circuit board structures, which brings great convenience for subsequent circuit board manufacturing and simplifies the manufacturing process.

### CROSS REFERENCES TO RELATED APPLICATION

This application is a continuation of U.S. application Ser. No. 17/753,107, entitled “Method for preparing novel material layer structure of circuit board and article thereof”, filed Feb. 18, 2022, and the entire contents of which are incorporated herein by reference.

### TECHNICAL FIELD

The present invention relates to the field of circuit boards, and more particularly, to a method for preparing a novel material layer structure of a circuit board and an article thereof.

### BACKGROUND ART

At present, the communication frequency is overall high-frequency from the communication network to the terminal application. High-speed and large-capacity applications emerge endlessly. As wireless networks transition from 4G to 5G in recent years, network frequencies continue to rise. According to the 5G development roadmap shown in the relevant data, the future communication frequency will be promoted in two stages. The first phase aims to increase the communication frequency to 6 GHz by 2020, and the second phase to further increase it to 30-60 GHz by 2020. In the market application, the signal frequency of terminal antennas such as smart phones is increasing. There are more and more high-frequency applications, which acquire more and more demand for high-speed and large-capacity. To adapt to the current trend of high-frequency and high speed from wireless networks to terminal applications, soft boards, as antennas and transmission lines in terminal devices, will also be subject to technological upgrading.

The conventional soft board has a multi-layer structure composed of a copper foil, an insulating substrate, a cover layer and the like, with the copper foil as a conductor circuit material, a PI film as a circuit insulating substrate, and a PI film and an epoxy adhesive as a cover layer for protecting and isolating a circuit, which are processed into a PI soft board by a certain process. Since the properties of the insulating substrate determine the final physical and electrical properties of the soft board, the soft board needs to use substrates with various performance characteristics in order to adapt to different application scenarios and functions. Polyimide (PI) is the most widely used soft board substrate at present. However, due to the larger dielectric constant and loss factor, higher moisture absorption and poor reliability of PI substrate, the high-frequency transmission loss of PI soft board is serious and its structural characteristics are poor, which cannot adapt to the current high-frequency and high-speed trend. Therefore, with the emergence of new 5G technology products, the signal transmission frequency and speed of existing circuit boards have been difficult to meet the requirements of 5G technology products.

Meanwhile, in the preparation technique, there are many problems in the traditional multi-layer flexible circuit board or multilayer combination of hard and soft boards, such as more process flows, complex manufacturing process, and higher power consumption and signal transmission loss in circuit board performance.

Also, the copper ion migration phenomenon will usually occur between the lines when the circuit board in the precise line is powered on. During the use of the device, there will be a risk that the circuit will burn and explode due to the conductive collision between the lines, resulting in that the lines on the circuit board cannot work safely and normally.

### SUMMARY OF THE INVENTION

In view of the above-mentioned deficiencies, it is an object of the present invention to provide a method for preparing a novel material layer structure of a circuit board and an article thereof, wherein the prepared novel material layer structure of the circuit board has high-frequency characteristics and/or copper ion migration resistance; and the novel material layer structure of the circuit board, as an integral structure, can be used as a manufacturing material of the circuit board in a subsequent manufacturing process of the circuit board to prepare a circuit board structure such as a single-layer circuit board, a multi-layer flexible circuit board and a multi-layer soft-hard combined board, which brings great convenience to the subsequent manufacturing of the circuit board, simplifies the manufacturing process, accelerates the manufacturing speed of the circuit board, and reduces production costs.

The technical solution adopted by the invention for achieving the above purpose is as follows.

A method for preparing a novel material layer structure of a circuit board is characterized by comprising the steps of:
(1) combining a film with a copper layer to form an FCCL single-sided board;
(2) placing the FCCL single-sided board in a film covering machine, and applying a semi-cured functional material layer on the back of the film at a temperature of 60° C.-500° C., wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive to form a novel material layer structure for a circuit board.

As a further improvement of the present invention, in the step (2), a front surface and a back surface of the semi-cured functional material layer are provided with a release paper or a PET release film, respectively; and the release paper or the PET release film on the front surface of the semi-cured functional material layer is torn off before the semi-cured functional material layer is applied to the back surface of the film.

As a further improvement of the invention, the step (2.2) specifically comprises the steps of:

(3) tearing off the release paper or the PET release film on the back side of the semi-cured functional material layer, and hot-pressing a copper foil on the back surface of the semi-cured functional material layer to form a novel double-sided material layer structure of a circuit board.

As a further improvement of the present invention, the semi-cured functional material layer is any one of an MPI film, an LCP film, a TFP film and a PTFE film.

As a further improvement of the present invention, in the step (1), the copper foil is laminated on the film to realize the combination of the film and the copper layer.

As a further development of the invention, in the step (1), copper is sputtered on the film to realize the combination of the film and the copper layer.

As a further improvement of the present invention, in the step (1), the film is any one of a PI film, an MPI film, an LCP film, a TFP film, and a PTFE film.

As a further improvement of the present invention, in the step (2), the copper ion migration resistant film is obtained by adding a copper ion scavenger to the PI film, followed by high purification; the copper ion migration resistant adhesive is obtained by adding the copper ion scavenger in an AD adhesive, followed by high purification; and the LDK high-frequency functional adhesive is obtained by adding Teflon or LCP material the AD adhesive.

As a further improvement of the present invention, in the step (2), a colored filler is added to at least one of the semi-cured high-frequency material layer and the film.

As a further refinement of the invention, the colored filler is a carbide.

A novel material layer structure of a circuit board prepared by performing the method is characterized by comprising a copper layer, a film and a semi-cured functional material layer sequentially stacked from top to bottom, wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive.

As a further improvement of the present invention, the film is any one of a PI film, an MPI film, an LCP film, a TFP film and a PTFE film.

As a further development of the invention, the copper layer is copper foil or sputtered copper.

As a further improvement of the present invention, a release paper or PET release film is provided on a lower surface of the semi-cured functional material layer.

As a further improvement of the present invention, a copper foil layer is hot-pressed on the lower surface of the semi-cured functional material layer; the semi-cured functional material layer is the same as the material of the film; and the semi-cured functional material layer is integrated with the film.

As a further improvement of the present invention, at least one of the film and the semi-cured functional material layer is a colored layer.

The invention has the following beneficial effects.

(1) A semi-cured functional material layer with special properties is applied on an FCCL single-sided board, so that the novel material layer structure of the circuit board with high-frequency characteristics and/or copper ion migration resistance can be prepared. As an integral structure, this novel material layer structure of the circuit board can be used as a circuit board manufacturing material in subsequent circuit board manufacturing processes; and a circuit board structure such as a single-layer circuit board, a multi-layer flexible circuit board and a multi-layer soft-hard combined board can be manufactured by subsequent direct hot-pressing processes with other materials or circuit boards, which brings great convenience for subsequent circuit board manufacturing. Therefore, it can simplify the manufacturing process, accelerate the manufacturing speed of the circuit board, shorten the processing time of the product, improve the processing capacity of the process and reduce the production cost. Furthermore, the product structure is optimized and the product performance is improved.

(2) MPI film, LCP film, TFP film or PTFE film, instead of the traditional PI thin film, is used as the substrate required for preparing the novel material layer structure of the circuit board, which can not only improve the stability and dimensional stability of the overall performance of the circuit board, but also have high-frequency characteristics. It can transmit high-frequency signals, speed up the transmission speed of high-frequency signals, and achieve high-speed transmission of high-frequency signals, with low power consumption and high-frequency signal transmission loss, improving the signal transmission performance of the circuit board. It can adapt to the current high-frequency and high-speed trend from wireless networks to terminal applications, especially for new 5G technology products.

(3) An Mpi film, an LCP film, a TFP film, a PTFE film, an LDK high-frequency functional adhesive, or a mixture of the LDK high-frequency functional adhesive and the copper ion migration resistant adhesive are used as the semi-cured functional material layer to replace the traditional semi-cured AD adhesive, so that the prepared new material layer structure of the circuit board has high-frequency characteristics, can transmit high-frequency signals, and speed up the transmission speed of high-frequency signals to achieve high-speed transmission of high-frequency signals with low power consumption and high-frequency signal transmission loss, further improving the signal transmission performance of circuit board. It can adapt to the current high-frequency and high-speed trend from wireless networks to terminal applications, especially for new 5G technology products.

(4) A copper ion migration resistant film or a copper ion migration resistant adhesive is applied as a semi-cured functional material layer to replace the traditional semi-cured AD adhesive, so that the prepared novel material layer structure of the circuit board has the function of resistant to copper ion migration, which can effectively ensure that the circuit board can work safely and effectively in the working state; and no migration of copper ions will occur between the circuits when the circuit board is powered on. During the use of the device, the migration of copper ions between the circuits is prevented, so as to prevent the occurrence of circuit short circuit, combustion and fire caused by circuit conduction, battery explosion, and functional failure and other hazards, so that the circuit plays a good protective role.

The above is an overview of the technical scheme of the invention. The following is a further explanation of the invention in combination with the attached drawings and specific implementations.

### BRIEF DESCRIPTION OF THE DRAWINGS

FIG. 1 is a structurally cross-section view according to Embodiment 1;

FIG. 2 is a structurally cross-section view according to Embodiment 2;

### DETAILED DESCRIPTION OF THE INVENTION

In order to further explain the technical means and effects of the present invention for achieving the intended purpose, the following detailed description of the embodiments of the present invention will be made with reference to the accompanying drawings and preferred embodiments.

### Embodiment 1

This embodiment provides a method for preparing a novel material layer structure of a circuit board, comprising the steps of:

(1) combining a film with a copper layer to form an FCCL single-sided board;

(2) placing the FCCL single-sided board in a film covering machine, and applying a semi-cured functional material layer on the back of the film at a temperature of 60° C.-500° C., wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive to form a novel material layer structure for a circuit board.

In the step (2), a front surface and a back surface of the semi-cured functional material layer are provided with a release paper or a PET release film, respectively; and the release paper or the PET release film on the front surface of the semi-cured functional material layer is torn off before the semi-cured functional material layer is applied to the back surface of the film. In the step (1), for the process of combining the film with the copper layer, there may be two:

The first one: the copper foil is laminated on the film to realize the combination of the film and the copper layer.

The second one: copper is sputtered on the film to realize the combination of the film and the copper layer.

The novel material layer structure of the circuit board prepared in this embodiment can form a single-layer circuit board in a later process as long as a circuit is formed on a copper foil, and then a layer of PI film and a layer of adhesive are successively hot-pressed on the copper foil on which the circuit is formed.

Meanwhile, after forming a circuit on the copper foil, the novel material layer structure of the circuit board prepared in this embodiment is laminated in multiple groups to form a multi-layer flexible circuit board. In the specific lamination, the semi-cured functional material layer of the novel material layer structure of the first group of circuit boards is laminated together with the copper foil formed with the circuit in the novel material layer structure of the second group of circuit boards.

Meanwhile, a multi-layer soft-hard combining board can be formed by integrally hot-pressing the novel material layer structure of the circuit board onto a glass fabric with an adhesive on both sides, hot-pressing a copper foil on one side of the glass fabric away from the material layer structure of the circuit board, and then forming a circuit on the copper foil, wherein the adhesive of the both sides of the glass fabric is at least one of an copper ion migration resistant adhesive and an LDK high-frequency functional adhesive.

Of course, it is also possible to directly hot-press the novel material layer structure of the circuit board to other circuit boards, and the semi-cured functional material layer on the novel material layer structure of the circuit board and the other circuit boards are in contact and hot-pressed and integrated.

Specifically, in the step (1), the film is any one of a PI film, an MPI film, an LCP film, a TFP film, and a PTFE film.

The types and characteristics of semi-cured functional material layers and films are as follows.

Pi film is polyimide film, which is a good film-like insulating material, and is prepared from pyromellitic dianhydride (PMDA) and diamino diphenyl ether (DDE) by polycondensation and casting in a strong polar solvent and then imidization. Pi film has excellent high and low temperature resistance, electrical insulation, adhesion, radiation resistance and dielectric resistance, and can be used for a long time in the temperature range of −269° C.˜ 280° C., which can reach high temperature of 400° C. in a short time. The vitrification temperatures are 280° C. (Upilex R), 385° C. (Kapton) and above 500° C. (Upilex S), respectively. The tensile strength is 200 MPa at 20° C. and greater than 100 MPa at 200° C. It is particularly suitable as a substrate for flexible circuit boards.

MPI (Modified PI) is a modified polyimide, i. e. modified by a polyimide (PI) formulation. MPI, because it is a non-crystalline material, has a wide operating temperature. It is easy to handle during the copper foil pressing at low temperature, has a surface capable of bonding with copper, and is inexpensive. Specifically, the fluoride formulation is improved, so that the MPI film can transmit a high-frequency signal of 10-15 GHz. Using MPI film as the substrate required for preparing the novel material layer structure of the circuit board in the embodiment is particularly suitable for preparing a flexible circuit board for the purpose of high-speed, stable reception and transmission of information; and terminal applications include such as 5G mobile phones, high-frequency signal transmission fields, automatic driving, radar, cloud servers and smart homes.

With speed measurement, the technical indicators of MPI film include:

| Performance | | Test Value | | Standard |
|---|---|---|---|---|
| Peel strength (kgf/cm) | (A) | 0.84 | | ≤0.7 |
| Dielectric constant Dk | 10 GHz | 2.79 | | ≤3.0 |
| Loss factor Df | 10 GHz | 0.0049 | | ≤0.005 |
| Dimensional stability | Method B | MD: 0.03 TD: 0.02 | | ≤±0.15 |
| (%) | Method C | MD: 0.06 TD: 0.04 | | |
| Resistance (%) | 10% HCl/ | 0.77 | reduction | ≤20% |
| | 10 min | | rate = 8.3% | |
| | 10% NaOH/ | 0.83 | reduction | |
| | 10 min | | rate = 1.2% | |
| | IPA/ | 0.76 | reduction | |
| | 10 min | | rate = 9.5% | |

| | | | |
|---|---|---|---|
| Flame retardancy | UL-94 V0 | Pass | UL-94 V0 |

It can be seen from the above that the MPI film has the following properties.
(1) Low Dk value, low Df value;
(2) Excellent heat aging resistance;
(3) Excellent dimensional stability;
(4) Excellent chemical Resistance.

Therefore, using the MPI film as the substrate required for preparing the novel material layer structure of the circuit board in the embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

LCP, all known as Liquid Crystal Polymer, is a novel thermoplastic organic material that generally exhibit a liquid crystalline property in the molten state. LCP film is a liquid crystal polymer film. LCP film has the properties of high strength, high rigidity, high temperature resistance, thermal stability, bendability, dimensional stability, and good electrical insulation, etc., and has better water resistance than PI film. Therefore, it is a film-type material superior to the PI film. LCP film can achieve high-frequency and high-speed soft board with high reliability. LCP films have the following excellent electrical characteristics.

(1) A constant dielectric constant can be maintained in all radio frequency ranges up to 110 GHz with good consistency; and the specific value of dielectric constant Dk is 2.9.

(2) Tangent loss is very small, only 0.002, even only increased to 0.0045 at 110 GHZ, which is very suitable for millimeter wave applications.

(3) The thermal expansion characteristic is very small. It can be used as an ideal high-frequency packaging material.

The use of LCP film as the substrate required for forming the circuit in this embodiment can not only improve the stability and dimensional stability of the overall performance of the circuit board, but also have less LCP film material medium loss and conductor loss due to the smoother overall LCP film; meanwhile, it has flexibility and sealing, can transmit high-frequency signals, and accelerate the transmission speed of high-frequency signals, which can improve the signal transmission performance of the circuit board and can adapt to the current high-frequency high-speed trend from wireless network to terminal applications.

Specifically, it can effectively improve the speed at which the circuit board transmits the command issued by the central area (chip) in the working state, and quickly transmit the command to each component, so that the device (such as mobile phone and communication base station device) can operate quickly without the phenomena of slowness or jam, and the communication process is smooth as a whole. Therefore, LCP film has a good prospect for high-frequency devices, especially for new 5G technology products.

Meanwhile, the LCP soft board made of LCP film as the substrate has better flexibility, which can further improve the space efficiency compared with PI soft board. Flexible electronics can be further thinned with a smaller bend radius. Therefore, the pursuit of flexibility is also a manifestation of miniaturization. According to the judgment of resistance change of more than 10%, under the same experimental conditions, LCP soft board can endure more bending times and smaller bending radius than traditional PI soft board, so that LCP soft board has better flexibility performance and product reliability. The excellent flexibility makes it possible to design the shape of LCP soft board freely so as to make full use of the narrow space in smart phones and further improve the efficiency of space utilization.

Therefore, a miniaturized high-frequency high-speed LCP soft board can be manufactured using an LCP film as a substrate.

TFP is a unique thermoplastic material with the following properties compared to conventional PI materials.

(1) Low dielectric constant: a low Dk value, the Dk value being specifically 2.55; while the Dk value of conventional PI is 3.2; therefore, the signal propagation speed is faster, the thickness is thinner, and the spacing is closer; and the power processing capacity is higher.

(2) Ultra-low material loss.

(3) Ultrahigh temperature performance, withstanding a high temperature of 300° C.

(4) The moisture absorption rate is relatively low.

Therefore, using the TFP film as the substrate required for forming the circuit in this embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

PTFE, polytetrafluoroethylene, is also named Teflon. Polytetrafluoro ethylene (PTFE) has excellent dielectric properties, chemical resistance, heat resistance and flame resistance, and has small dielectric constant and dielectric loss and small change in high-frequency range. The main performances are as follows.
1. Electrical performance
(1) Dielectric constant: 2.1;
(2) Dielectric loss: 5×10⁻⁴;
(3) Volume resistance: 1018 Ω·cm;
2. Chemical performance: acid-alkali resistance, organic solvent resistance and oxidation resistance;
3. Thermal stability: long-term operation in the temperature range of −200° C.˜260° C.;
4. Flame retardancy: UL94V-0;
5. Weather resistance: there is no significant loss of mechanical properties outdoors for more than 20 years.

Therefore, using the PTFE film as the substrate required for preparing the novel material layer structure of the circuit board in the embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

The integration of 5G base station makes the demand of high-frequency copper clad laminate grow rapidly. As one of the mainstream high-frequency base materials of 5G high-frequency high-speed copper clad laminate, PTFE will meet the huge market growth in the 5G era.

It can be seen therefrom that using any one of the above-mentioned PI film, MPI film, LCP film, TFP film and PTFE film as the substrate required for preparing the novel material layer structure of the circuit board in the embodiment is particularly suitable for a flexible circuit board. Especially, the MPI film, LCP film, TFP film and PTFE film can not only improve the overall performance of the flexible circuit board, but also have a high-frequency characteristic, which can greatly accelerate the transmission of high-frequency signals, achieve high-speed transmission of high-frequency signals, and reduce power consumption and high-frequency signal transmission loss, particularly suitable for novel 5G technology products.

Of course, the semi-cured functional material layer may also be a copper ion migration resistant film obtained by adding a reagent such as a copper ion scavenger to the PI film, followed by high purification. Specifically, the PI film may be a conventional PI film. Optionally, the copper ion scavenger can be an inorganic ion exchangers (for example, IXE-700F, IXE-750, etc.) which have the ability to capture copper ions, and can prevent the migration of copper ions between circuits. After adding the copper ion scavenger to the PI film, the copper ion scavenger has no effect on the performance of the PI film, but can improve the performance stability of the PI film. After a high purification process, the purity of various components in the PI film can be improved; and the possibility of migration of copper ions between circuits from the PI film is significantly reduced for the purpose of resisting migration of copper ions. Specifically, the conventional PI film has a certain gap between each two components, and copper ions can migrate through the gap; however, when the conventional PI film is purified, the concentration of each component is significantly reduced, and the gap existing between each two components is greatly reduced, thereby reducing the gap available for copper ion migration, so as to achieve the purpose of resisting copper ion migration. Therefore, in addition to having the characteristics of PI film, the cured copper ion migration resistant film also has the function of low particle material copper ion migration resistance, which can effectively ensure that the circuit can work safely and effectively in the working state; and there will be no ion migration phenomenon between the circuits, so as to prevent the conducting collision between the circuits during the use of the device, resulting in short circuit and combustion and explosion hazards, so that the circuit plays a good safeguard and protection role.

The semi-cured functional material layer may also be an LDK high-frequency functional adhesive obtained by adding Teflon or LCP material to a conventional AD adhesive. However, the molecular distribution in the semi-cured LDK high-frequency functional adhesive is more compact and uniform, which does not consume energy, so that the LDK high-frequency functional adhesive has the functions of improving the signal transmission frequency and resisting magnetic interference, so as to improve the signal transmission performance of the circuit board. Specifically, it can effectively improve the speed at which the circuit board transmits the command issued by the central area (chip) in the working state, and quickly transmit the command to each component, so that the device (such as mobile phone and communication base station device) can operate rapidly without the phenomena of slowness and jam, and the whole communication process of new 5G technology products is smooth.

In the case of the semi-cured functional material layer being as the copper ion migration resistant adhesive, it is obtained by adding a reagent such as a copper ion scavenger to the AD adhesive, followed by high purification. In particular, the liquid AD adhesive may be a conventional AD adhesive. Optionally, the copper ion scavenger can be an inorganic ion exchangers (for example, IXE-700F, IXE-750, etc.) which have the ability to capture copper ions, and can prevent the migration of copper ions between circuits. After adding the copper ion scavenger to the AD adhesive, the copper ion scavenger has no effect on the performance of the AD adhesive, but can improve the performance stability of the AD adhesive. The conventional AD adhesive contains epoxy resin, tackifier, plasticizer and various fillers; and after a high purification process, the purity of the epoxy resin component in the AD adhesive is improved, and the possibility of migration of copper ions between circuits from the AD adhesive is significantly reduced, achieving the purpose of resisting migration of copper ions. Specifically, the conventional AD adhesive has a certain gap between each two components, and copper ions can migrate through the gap; however, when the concentration of the epoxy resin purified from the conventional AD adhesive is increased, the concentration of other components is significantly reduced, and the gap existing between the epoxy resin and other components is greatly reduced, thereby reducing the gap available for copper ion migration, so as to achieve the purpose of resisting copper ion migration. Since the copper ion migration resistant adhesive has the anti-copper ion migration function of the low-particle material, it can effectively ensure that the circuit can work safely and effectively in the working state, and there will be no ion migration phenomenon between the circuits, so as to prevent the conducting collision between the circuits during the use of the device, resulting in short circuit and combustion and explosion hazards, so that the circuit plays a good safeguard and protection role.

When the semi-cured functional material layer is a mixture of an LDK high-frequency functional adhesive and a copper ion migration resistant adhesive, it is sufficient to mix the LDK high-frequency functional adhesive and the copper ion migration resistant adhesive, so that the semi-cured high-frequency material has both high-speed transmission high-frequency signals and copper ion migration resistant properties.

In this embodiment, the film and the semi-cured functional material layer may be made of the same material or may be made of different materials. For example, the film and the semi-cured functional material layer are both a film type, or the film is a film type; and the semi-cured functional material layer is an adhesive type. When the film and the semi-cured functional material layer are both films, it is preferable that the film and the semi-cured functional material layer are both MPI films; the film and the semi-cured functional material layer are both LCP films; the film and the semi-cured functional material layer are both TFP films; or the film and the semi-cured functional material layer are both PTFE films.

In the step (2), the semi-cured functional material layer and the film may be the color of the material itself or may be a transparent color.

Of course, a colored filler may also be added to at least one of the semi-cured functional material layer and the film. Specifically, the colored filler can be a carbide or other colored filler. The semi-cured functional material layer (specifically, it can be an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive) and a film (specifically, it can be any one of a PI film, an MPI film, an LCP film, a TFP film and a PTFE film), after being added a colored filler can exhibit a corresponding color, such as black, red, green, blue, color, etc. Whether the material layer structure of the circuit board prepared in this embodiment is made into a single-layer circuit board, a multi-layer flexible circuit board, or a multi-layer soft-hard combined board, the black semi-cured functional material layer and the thin film have a shielding effect on the circuit, which can prevent the internal circuit from being exposed, and prevent the external person from seeing the internal circuit from the outside, and play the role of concealing and protecting the circuit on the circuit board; meanwhile, it plays the role of masking defects for the circuit board or circuit with impurities or defects.

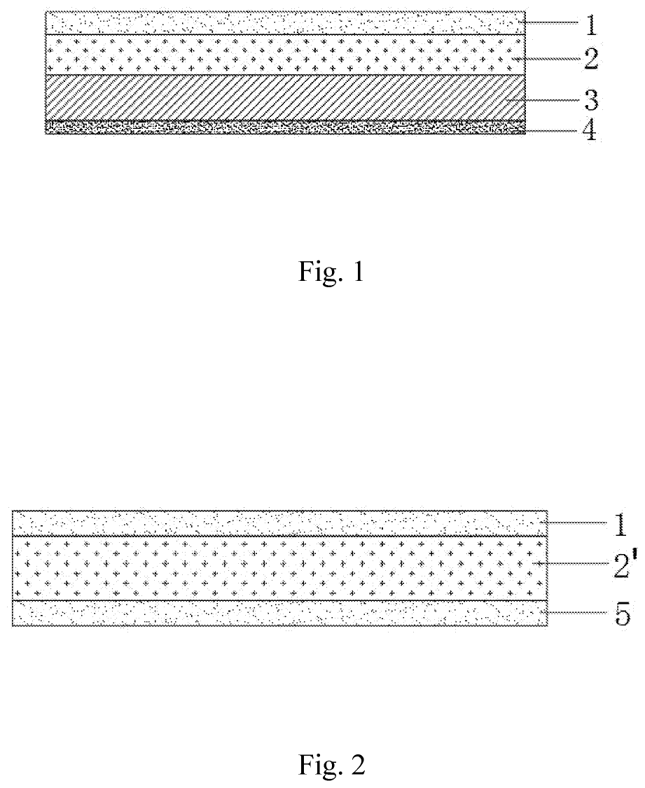

This embodiment also provides a novel material layer structure of a circuit board prepared by performing the above-mentioned method, as shown in FIG. 1, comprising a copper layer 1, a film 2 and a semi-cured functional material layer 3 which are successively stacked from top to bottom, wherein the copper layer 1 is a copper foil or sputtered copper; the semi-cured functional material layer 3 is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive.

In this embodiment, the semi-cured functional material layer 3 is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive. MPI film, LCP film, TFP film, PTFE film and LDK high-frequency functional adhesive can accelerate the frequency and speed of signal transmission, transmit high-frequency signals and improve the signal transmission performance of the circuit board, which can not only improve the overall performance of the flexible circuit board, but also have high-frequency characteristics. They can greatly accelerate the transmission of high-frequency signals and achieve high-speed transmission of high-frequency signals, especially suitable for new 5G technology products. However, the copper ion migration resistant film has the performance of copper ion migration resistance; and the mixture of the LDK high-frequency functional adhesive and the copper ion migration resistant adhesive has high-speed transmission high-frequency signals and copper ion migration resistant performance.

Specifically, the film 2 is any one of a PI film, an MPI film, an LCP film, a TFP film, and a PTFE film. Using any one of the above-mentioned PI film, MPI film, LCP film, TFP film and PTFE film as the substrate required for preparing the novel material layer structure of the circuit board in the embodiment is particularly suitable for a flexible circuit board. Especially, the MPI film, LCP film, TFP film and PTFE film can not only improve the overall performance of the flexible circuit board, but also have a high-frequency characteristic, which can greatly accelerate the transmission of high-frequency signals and achieve high-speed transmission of high-frequency signals, particularly suitable for novel 5G technology products.

In this embodiment, the film 2 and the semi-cured functional material layer 3 may be made of the same material or may be made of different materials. For example, the film 2 and the semi-cured functional material layer 3 are both a film type, or the film 2 is a film type; and the semi-cured functional material layer 3 is an adhesive type. When the film 2 and the semi-cured functional material layer 3 are both films, it is preferable that the film 2 and the semi-cured functional material layer 3 are both MPI films; the film 2 and the semi-cured functional material layer 3 are both LCP films; the film 2 and the semi-cured functional material layer 3 are both TFP films; or the film 2 and the semi-cured functional material layer 3 are both PTFE films.

Specifically, a release layer 4 is provided on a lower surface of the semi-cured functional material layer 3; the release layer 4 is a release paper or a PET release film, protecting the semi-cured functional material layer 3; and the release layer 4 can be peeled off during subsequent processing.

Specifically, at least one of the film 2 and the semi-cured functional material layer 3 is a colored layer. The colored layer can be specifically black; and the colored layer plays the role of shielding, protection, masking and so on for the internal circuit.

### Embodiment 2

The main differences between this embodiment and embodiment 1 are as follows. It further comprises step (3) of tearing off the release paper or the PET release film on the back side of the semi-cured functional material layer, and hot-pressing a copper foil on the back surface of the semi-cured functional material layer to form a novel double-sided material layer structure of a circuit board.

Meanwhile, the semi-cured functional material layer described in this embodiment is any one of an MPI film, an LCP film, a TFP film, and a PTFE film. Furthermore, the semi-cured functional material layer and the film are of the same material. For example, the film and the semi-cured functional material layer are both an MPI film; the film and the semi-cured functional material layer are both an LCP film; the film and the semi-cured functional material layer are both a TFP film; or the film and the semi-cured functional material layer are both a PTFE film.

Therefore, a double-sided novel material layer structure of a circuit board can be prepared by the above-mentioned method; and a copper foil layer 5 is hot-pressed on the lower surface of the semi-cured functional material layer 3, as shown in FIG. 2, to form a novel double-sided material layer structure of a circuit board. Meanwhile, the semi-cured functional material layer 3 has the same material as that of the film 2. Since the copper foil layer 5 is hot-pressed, the semi-cured functional material layer 3 is cured and integrated with the film 2, namely, integrated into a composite film layer 2′.

In the description above, only the preferred embodiments of the present invention has been described, and the technical scope of the present invention is not limited in any way. Therefore, other structures obtained by adopting the same or similar technical features as those of the above embodiments of the present invention are within the scope of the present invention.

1. A method for preparing a novel material layer structure of a circuit board, characterized by comprising the steps of:
(1) combining a film with a copper layer to form an FCCL single-sided board;
(2) placing the FCCL single-sided board in a film covering machine, and applying a semi-cured functional material layer on the back of the film at a temperature of 60° C.-500° C., wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive to form a novel material layer structure for a circuit board.

2. The method for preparing a novel material layer structure of a circuit board according to claim 1, characterized in that in the step (2), a front surface and a back surface of the semi-cured functional material layer are provided with a release paper or a PET release film, respectively; and the release paper or the PET release film on the front surface of the semi-cured functional material layer is torn off before the semi-cured functional material layer is applied to the back surface of the film.

3. The method for preparing a novel material layer structure of a circuit board according to claim 2, characterized by further comprising the steps of:
(3) tearing off the release paper or the PET release film on the back side of the semi-cured functional material layer, and hot-pressing a copper foil on the back surface of the semi-cured functional material layer to form a novel double-sided material layer structure of a circuit board.

4. The method for preparing a novel material layer structure of a circuit board according to claim 3, characterized in that the semi-cured functional material layer is any one of an MPI film, an LCP film, a TFP film and a PTFE film.

5. The method for preparing a novel material layer structure of a circuit board according to claim 1, characterized in that in the step (1), the copper foil is laminated on the film to realize the combination of the film and the copper layer.

6. The method for preparing a novel material layer structure of a circuit board according to claim 1, characterized in that in the step (1), copper is sputtered on the film to realize the combination of the film and the copper layer.

7. The method for preparing a novel material layer structure of a circuit board according to claim 1, characterized in that in the step (1), the film is any one of a PI film, an MPI film, an LCP film, a TFP film, and a PTFE film.

8. The method for preparing a novel material layer structure of a circuit board according to claim 7, characterized in that in the step (2), the copper ion migration resistant film is obtained by adding a copper ion scavenger to the PI film, followed by high purification; the copper ion migration resistant adhesive is obtained by adding the copper ion scavenger in an AD adhesive, followed by high purification; and the LDK high-frequency functional adhesive is obtained by adding Teflon or LCP material the AD adhesive.

9. The method for preparing a novel material layer structure of a circuit board according to claim 1, characterized in that in the step (2), a colored filler is added to at least one of the semi-cured functional material layer and the film.

10. The method for preparing a novel material layer structure of a circuit board according to claim 9, characterized in that the colored filler is carbide.

11. A novel material layer structure of a circuit board prepared by performing the method as claimed in claim 1, characterized by comprising a copper layer, a film and a semi-cured functional material layer sequentially stacked from top to bottom, wherein the semi-cured functional material layer is an MPI film, an LCP film, a TFP film, a PTFE film, a copper ion migration resistant film, an LDK high-frequency functional adhesive, a copper ion migration resistant adhesive, or a mixture of the LDK high-frequency functional adhesive and the copper ion migration resistant adhesive.

12. The novel material layer structure of a circuit board according to claim 11, characterized in that the film is any one of a PI film, an MPI film, an LCP film, a TFP film and a PTFE film.

13. The novel material layer structure of a circuit board according to claim 11, characterized in that the copper layer is copper foil or sputtered copper.

14. The novel material layer structure of a circuit board according to claim 11, characterized in that a release paper or PET release film is provided on a lower surface of the semi-cured functional material layer.

15. The novel material layer structure of a circuit board according to claim 12, characterized in that a copper foil layer is hot-pressed on the lower surface of the semi-cured functional material layer; the semi-cured functional material layer is the same as the material of the film; and the semi-cured functional material layer is integrated with the film.

16. The novel material layer structure of a circuit board according to claim 11, characterized in that at least one of the film and the semi-cured functional material layer is a colored layer.
